(19) United States
(12) Patent Application Publication
(10) Pub. No.: US 2007/0273281 A1
(43) Pub. Date: Nov. 29, 2007

(54) Organic light emitting device

(76) Inventor: Alexander Biebel, BICKENBACH (DE)

Correspondence Address: OHLANDT, GREELEY, RUGGIERO & PERLE, LLP, ONE LANDMARK SQUARE, 10TH FLOOR, STAMFORD, CT, 06901, US

(21) Appl. No.: 10/561,598

(22) PCT Filed: Jun. 16, 2004
(86) PCT No.: PCT/EP04/06470

§ 371 Date: Mar. 27, 2007

(30) Foreign Application Priority Data
Jun. 20, 2003 (DE) 103 28 140.1

(51) Int. Cl. H01J 1/62; H01J 63/04

(52) U.S. Cl. 313/512; 313/506

(57) ABSTRACT

The invention relates to an OLED and a method for producing it. It is an object to improve the OLED with regard to its safety properties and, if appropriate, to pattern it. According to the invention, an antishatter protective layer is applied to the OLED, which is photopatterned, in particular, thereby fulfilling a multiple function. The formation of an antishatter protective composite element with a glass-plastic-glass layer sequence is particularly advantageous.

### CROSS-REFERENCE TO RELATED APPLICATIONS

This application claims the benefit under 35 U.S.C. §365 of International Patent Application No. PCT/EP2004/006470, filed Jun. 20, 2003, the entire contents of which are incorporated by reference herein.

### FIELD OF THE INVENTION

The invention relates generally to an organic light emitting device and a method for producing it, and specifically to an OLED having an encapsulated organic light emitting layer arrangement.

### BACKGROUND OF THE INVENTION

Electro-optical components, in particular organic electroluminescent light emitting diodes (OLED), are of great interest for display applications and in the field of light technology since they have diverse advantages over other luminous and display means. Thus, OLEDs can be produced such that they are very thin and even flexible. Compared with liquid crystal displays, OLEDs have the advantage of being self-luminous. OLEDs are therefore the subject of intensive development work.

OLEDs are generally constructed from a layer composite comprising an organic electroluminescent layer between two electrode layers, which is applied on a suitable substrate. It is typically the case in an OLED that one of the conductive layers respectively acts as a cathode and the other as an anode. For this purpose, it is known to produce the electrode layers from materials having different work functions, so that a work function difference is formed between these layers.

Known OLED components are typically deposited on glass substrates. The OLED coating is subsequently encapsulated by means of a solid cover. The cover generally comprises glass or metal and may be embodied as a plate or housing. The cover is connected and sealed to the glass substrate by means of epoxy-resin-based adhesives (cf. Appl. Phys. Lett. 65, 2922 (1994)).

OLEDs are distinguished by particular advantages compared with other luminous means. Thus, OLEDs have the major advantage over LCDs or liquid crystal displays that they are self-luminous. Moreover, OLEDs can be produced as thin, flexible films which are particularly suitable for specific applications in light and display technology.

However, this advantage of the small thickness is accompanied by a difficulty, namely the fracture sensitivity of an OLED. This difficulty is thereby also considerably exacerbated insofar as glass substrates are used.

Particularly in areas in which an OLED is to be handled by a user, e.g. in the case of mechanically stressed display applications that come into contact with the body, this gives rise to a potential risk of injury. Therefore, there is a need for OLEDs having improved safety properties.

A second objective in OLED technology is to be able to provide patterned luminous areas. Accordingly, local fixed brightness differences have to be produced on the luminous area. This opens up a wide variety of fields of use, e.g. the possibility of using the OLED as a self-luminous nameplate, company logo, or as a patterned luminous area in shop windows, to mention just two of many examples. However, the safety aspect is again often of primary importance precisely in these applications.

For patterning in general, U.S. Pat. No. 5,660,573 and U.S. Pat. No. 3,201,633 describe electroluminescent capacitors in which the local brightness is likewise influenced by a patterned dielectric intermediate layer.

However, the operation of an electroluminescent capacitor requires a high-frequency alternating current in order to achieve sufficiently high excitation of the electroluminescent material. Said current leads to high emission of electromagnetic fields at the large-area electrodes. Furthermore, relatively high voltages are used. This once again results in multiple potential endangering of the user.

It is also known to modulate the emitted light indirectly by influencing the local current density through the organic electroluminescent layer. This is possible by means of a corresponding lateral patterning of the electrodes.

It is also known to interrupt the current flow through the layer system of the OLED layer composite by means of insulator structures or structures having a higher resistance that are additionally present in the layer composite. Moreover, the electroluminescent layer itself may also be laterally patterned.

WO 9803043 proposes a method in which a patterned insulator layer is applied photolithographically in order to produce a patterned luminous area.

A similar method is also proposed in JP 07-289988, where a homogeneous film is applied and subsequently patterned by exposure and development, a patterned polyurethane film being obtained on the electrode layer as a result.

However, these technologies have in common the serious disadvantage that the patterning requires special and complicated manufacturing technologies and the patterning usually even has to be carried out under clean room conditions.

Furthermore, the known technologies are extremely inflexible since even in the production of the OLED layer arrangement it is necessary to perform the patterning within the OLED.

To summarize, the technologies are suitable only to a limited extent for a series of mass applications involving specific safety requirements, on the one hand, and a considerable cost pressure, on the other hand.

### BRIEF SUMMARY OF THE INVENTION

The object set for the invention is to provide an OLED which satisfies increased safety requirements.

A further object of the invention is to provide an OLED having a patterned luminous area that is cost-effective and s simple to produce.

Yet another object of the invention is to provide an OLED, in particular for the mass market, which avoids or at least reduces the disadvantages of known OLEDs.

This object is achieved in an extremely surprising manner just by the subject matter of the present application. The respective subclaims relate to advantageous developments.

The invention provides an organic light emitting device, in particular an OLED, comprising a first substrate, an encapsulation or an encapsulation means and an organic light emitting layer arrangement, which is encapsulated between the first substrate and the encapsulation means or element. The substrate, the organic light emitting layer arrangement and the encapsulation means consequently form a light emitting encapsulated composite element or a light emitting layer composite.

The organic light emitting or electroluminescent layer arrangement comprises at least a first and second electrode or electrode layer, in particular an anode and a cathode, and, arranged in between, an organic electroluminescent layer or layer having an organic electroluminescent material.

By way of example, PEDOT or an electroluminescent polymer such as e.g. poly(2-methoxy-5-(2′-ethyl-hexyloxy)-paraphenylene vinylene) (MEH-PPV) is used as the electroluminescent material.

In order to be able to emit light through at least one of the electrode layers, in particular at least one of the two electrode layers is formed in conductive and transparent fashion. For visible light, preferably transparent conductive oxides (TCO), such as tin oxide or indium tin oxide (ITO), for example, are used for this purpose. However, inherently nontransparent materials, such as, in particular, metals, for example gold or silver, may also be transparent or partly transparent to the emitted light given a sufficiently small layer thickness or by means of suitable patterning, for example in the manner of a shadow mask.

In particular, the first substrate, which defines a front side of the organic light emitting device, is formed such that it is light-transmissive, so that during operation light is coupled out from the organic light emitting device through the first substrate via the front side.

Furthermore, on the front side or on the side on which light is coupled out through the first substrate, a functional layer is applied to the light emitting composite element, in particular to the first substrate. In this case, the choice of the word “applied” is to be understood to the effect that the functional layer is applied either directly or indirectly, that is to say if appropriate with the interposition of further layers, to or on the light emitting composite element, or the first substrate, more precisely its front side, or outside the light emitting composite element.

In particular, the first substrate defines an interior and an exterior with regard to the light emitting composite element, the light emitting composite element being applied to the interior and the functional layer being applied to the exterior. The functional layer is thus applied to the first substrate outside the encapsulation.

This has the considerable advantage over the known technologies that the light emitting composite element can be completed and sealed, in particular under clean room conditions, and the functional layer is subsequently applied to the sealed or encapsulated light emitting composite element, with the result that it is possible to avoid damaging, contaminating or otherwise disturbing the electroluminescent layer construction.

It is particularly advantageous if, in accordance with one preferred embodiment of the invention, the functional layer is formed as an antishatter protective layer. In this case, at least the first substrate and the antishatter protective layer form a first composite element. An antishatter protective layer is e.g. advantageous if the device is used as a self-luminous name badge for conference participants. This reduces the risk, if the name badge breaks e.g. in a crush, of injury to the person wearing said badge or other persons due to splinters of glass.

Preferably, the encapsulation or the encapsulation means comprises a second substrate, which, on an opposite side of the first substrate to the functional layer, is adhesively bonded onto said first substrate or the light emitting layer arrangement. As an alternative, with the second substrate being dispensed with, the encapsulation comprises only an adhesive with which the light emitting layer arrangement is potted.

As an alternative or in supplementary fashion, the encapsulation comprises a coating or a layer system, comprising e.g. one or more layers made of metal, ceramic and/or polymer.

It is furthermore preferred for a further third substrate to be applied on the functional layer, so that the functional layer is arranged between the first and third substrates and is connected thereto, and at least the first and third substrates and the antishatter protective layer form a second composite element or an antishatter protective composite arrangement. In other words, the antishatter protective layer is enclosed between the first and third substrates in sandwichlike fashion, the first substrate fulfilling a double function, namely firstly of forming a part of the encapsulation and coupling-out of light from the OLED, and secondly of forming a part of the antishatter protective composite arrangement.

A particularly effective antishatter protective effect is obtained if the first and third substrates and the antishatter protective layer are adhesively bonded in areal fashion to form an antishatter protective composite arrangement. This is advantageous in particular if at least one or a plurality of the substrates are glass substrates.

The antishatter protective effect can be reinforced further by using a hardened glass for the first, second and/or third substrate, in particular by one or a plurality of the substrates being tempered glass substrates.

The first, second and/or third substrate is furthermore preferably a glass-plastic composite, e.g. in each case a plastic-coated glass or a glass-plastic laminate.

Preferably, the functional layer is formed as a patterned mask or shadow mask or in other words comprises first and second sections, the first sections essentially being light-transmissive and the second sections essentially being light-opaque or at least light-attenuating.

A particularly advantageous synergistic effect arises in an embodiment in which the functional layer is simultaneously formed as an antishatter protective layer and a patterned mask and thus fulfils a further double function.

By this means, a safe and patterned OLED is advantageously provided.

Such a device may be used e.g. as a self-luminous name badge for conference participants.

In accordance with one preferred development, the functional layer may even be formed as a multicolor patterned mask. As an alternative, the functional layer may also be printed on in patterned fashion.

It may initially appear to the person skilled in the art to be disadvantageous to provide an unpatterned OLED with a simple external shadow mask in order to obtain patterned light emission, e.g. a self-luminous image or a self-luminous text, since part of the light is first generated and subsequently absorbed again, which is associated with an increased energy demand. However, for specific applications, such as e.g. luminous name badges, this apparent disadvantage is more than compensated for by the simplicity of production.

A plastic layer, e.g. an adhesively bonded-on plastic film, as the functional layer has proved to be particularly simple. The adhesive bonding or connection of the plastic layer or film to the first substrate and/or the further connections or adhesive bondings are formed e.g. by means of a crosslinking epoxy adhesive. As an alternative, it is also possible to use a spray adhesive or a self-adhesive film.

Preferably, the end sides of the first, second and/or third substrate and/or of the functional layer are uncovered and are post processed after the adhesive bonding, the organic light emitting device being formed in particular in a frameless fashion.

The first, second and/or third substrate preferably has a thickness of 10 μm to 2000 μm, particularly preferably between 30 μm and 800 μm. The first, second and/or third adhesive layer preferably in each case have a thickness of 3 μm to 100 μm. The total thickness or structural height of the organic light emitting device including the functional layer and/or the third substrate is preferably 150 μm to 10 mm, particularly preferably less than 5 mm or 4 mm.

The aforementioned dimensions constitute an advantageous compromise between small structural height and sufficient stability.

It is furthermore advantageous for one or more end sides of the layers of the organic light emitting device to be beveled in order to obtain, toward the front, an edge coupling-out of light and thus a luminous border.

Preferably, an—optionally rechargeable—battery and a switch for switching the device on and off are integrated s into the light emitting device, more precisely into a housing. Furthermore, a preferably magnetic holding clip may be provided, by means of which it is possible to actuate the switch for automatic switching on and off.

The invention is explained in more detail below on the basis of exemplary embodiments and with reference to the drawings, identical and similar elements being provided with identical reference symbols and the features of the different exemplary embodiments being able to be combined with one another.

### BRIEF DESCRIPTION OF THE FIGURES

In the figures:

FIG. 1 shows a schematic sectional drawing of a light emitting device in accordance with a first embodiment of the invention,

FIG. 2 shows a schematic sectional drawing of a light emitting device in accordance with a second embodiment of the invention,

FIG. 3 shows a plan view of a self-luminous name badge,

FIG. 4 shows a schematic sectional drawing along the section line A-A in FIG. 3, and

FIG. 5 shows a schematic sectional drawing of a light emitting device in accordance with a further embodiment of the invention.

### DETAILED DESCRIPTION OF THE INVENTION

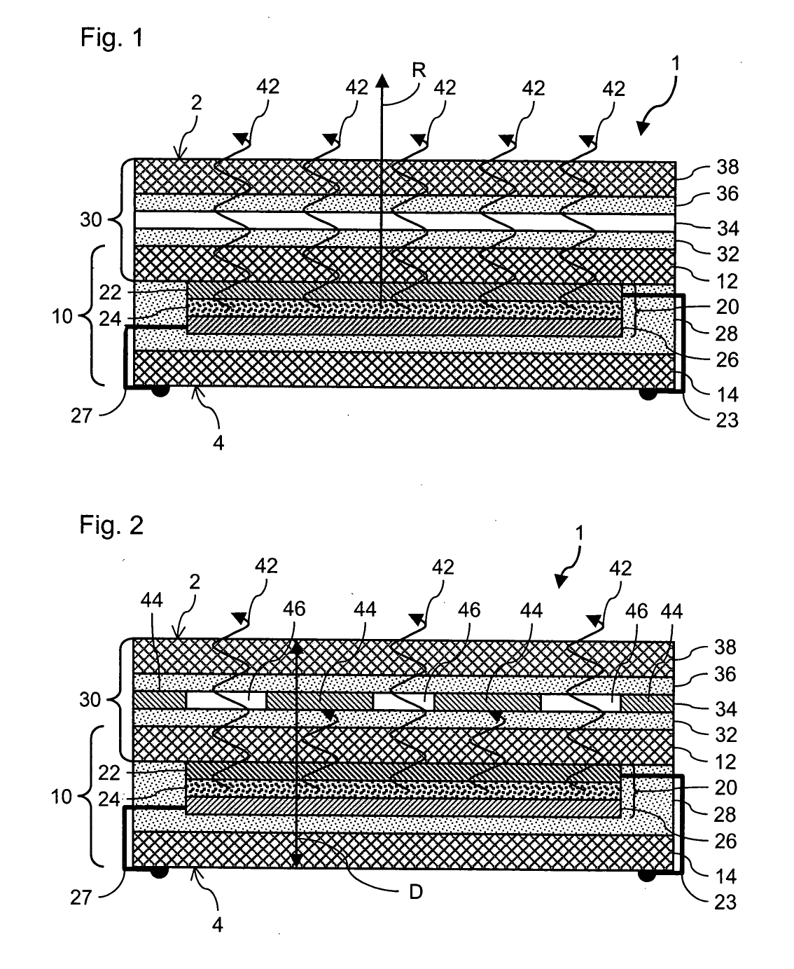

FIG. 1 shows an unpatterned organic light emitting device 1. The device 1 comprises a light emitting composite element 10 with a transparent base substrate 12 made of glass, onto which an organic light emitting layer arrangement 20 is applied or deposited, and with a covering substrate 14. The light emitting layer arrangement 20 in turn comprises a light emitting layer having electroluminescent material 24, e.g. an electroluminescent polymer, which is arranged between a transparent conductive ITO anode 22 and a metal cathode 26 and is contact-connected by them.

The light emitting layer arrangement 20 is potted with adhesive 28 on the rear side, the covering substrate 14 simultaneously being adhesively bonded on by means of the epoxy adhesive 28. A hermetic encapsulation of the light emitting layer arrangement 20 is thereby obtained.

The light generated in the device 1, represented by the arrows 42, is coupled out upwardly in the illustration, that is to say in the direction of the front side 2 of the device 1, through the transparent ITO layer 22 and the glass substrate 12.

The voltage supply is realized via leads 23, 27 which are led to the outside from the encapsulation 28 and can preferably be contact-connected on the rear side 4 of the device 1.

In this respect, the light emitting composite element 10 is an OLED construction that is known in principle to the person skilled in the art.

From the light emitting composite element 10, more precisely directly on the base substrate, from the outside now a functional layer or antishatter protective layer 34 in the form of a plastic film, e.g. a polyethylene film, is applied or adhesively bonded onto the base substrate 12 by means of an epoxy adhesive layer 32 from the outside, that is to say on an opposite side of the base substrate to the light emitting layer arrangement 20. In accordance with this example, the antishatter protective layer 34 is formed such that it is transparent over the whole area, that is to say in unpatterned fashion, in order to be able to emit the light 42 via the entire front side 2 of the device 1.

Furthermore, a protective substrate 38 made of glass is adhesively bonded on the front side of the plastic film 34 by means of a further adhesive layer 36. The glass substrate 38 protects the plastic film 34 from damage, such as e.g. scratches. As an alternative, the base substrate 12, the covering substrate 14 and/or the protective substrate 38 may also comprise plastic, e.g. in each case be a plastic film.

Thus, the base substrate 12 and covering substrate 14 are adhesively bonded to one another by means of the adhesive layer 28, the base substrate 12 together with the functional layer or antishatter protective film 34 are adhesively bonded to one another by means of the adhesive layer 32, and the antishatter protective layer 34 and the protective substrate 38 are adhesively bonded to one another by means of the adhesive layer 36, in each case in pairs.

Overall, the base substrate 12, the plastic film 34 and the protective substrate 38 adhesively bonded by means of the epoxy adhesive layers 32 and 36 form a glass-plastic composite element or laminate 30. The desired antishatter protective effect is obtained through the composite of the different materials. Said effect can also be improved by using a tempered glass for at least one of the substrates 12, 14, 38.

FIG. 2 shows a similar construction to FIG. 1. In a departure, however, the antishatter protective layer 34 is formed in patterned fashion. In this example, the patterning was obtained by photo patterning of a light-sensitive film 34.

In other words, the layer 34 has blackened or light-opaque, but at least light-attenuating, sections 44 and light-transmissive or transparent sections 46. As a result, the light 42 is masked out by the layer according to the principle of a shadow mask, so that a patterned luminous area arises.

What is particularly advantageous about this embodiment is that the layer 44 simultaneously fulfils the antishatter protective function and the mask function, so that the production process is simplified and a small structural height is obtained.

In this example the thicknesses of the layers are:

| | | |
|---|---|---|
| Covering substrate 14 | 1 | mm |
| Adhesive layer 28 and light | 50 | μm |
| emitting layer arrangement 20 | | |
| Base substrate 12 | 1 | mm |
| Adhesive layer 32 | 50 | μm |
| Antishatter protective film 34 | 100 | μm |
| Adhesive layer 32 | 50 | μm |
| Protective substrate 38 | 1 | mm |

so that an overall structural height or thickness of only approximately 3.25 mm is achieved in this example.

The inventors have found, however, that the device according to the invention may have a sufficient stability even with the following thicknesses:

| | |
|---|---|
| Covering substrate 14 | 50 μm |
| Adhesive layer 28 and light | 10 μm |
| emitting layer arrangement 20 | |
| Base substrate 12 | 50 μm |
| Adhesive layer 32 | 10 μm |
| Antishatter protective film 34 | 10 μm |
| Adhesive layer 32 | 10 μm |
| Protective substrate 38 | 50 μm |

so that, surprisingly, an overall structural height of less than 200 μm can be obtained and the device is thus even flexible or elastic to a certain extent.

The thickness of the functional layer 34 or antishatter protective film is preferably between 10 μm and 500 μm, however.

Particularly if a device with a small substrate thickness, that is to say in the region of less than 500 μm, is produced, it is advantageous to form the essential planar substrates 12, 14 and/or 38 themselves as a glass-plastic composite or laminate. The inventors have established that polymer-coated or -laminated glass substrates are particularly suitable.

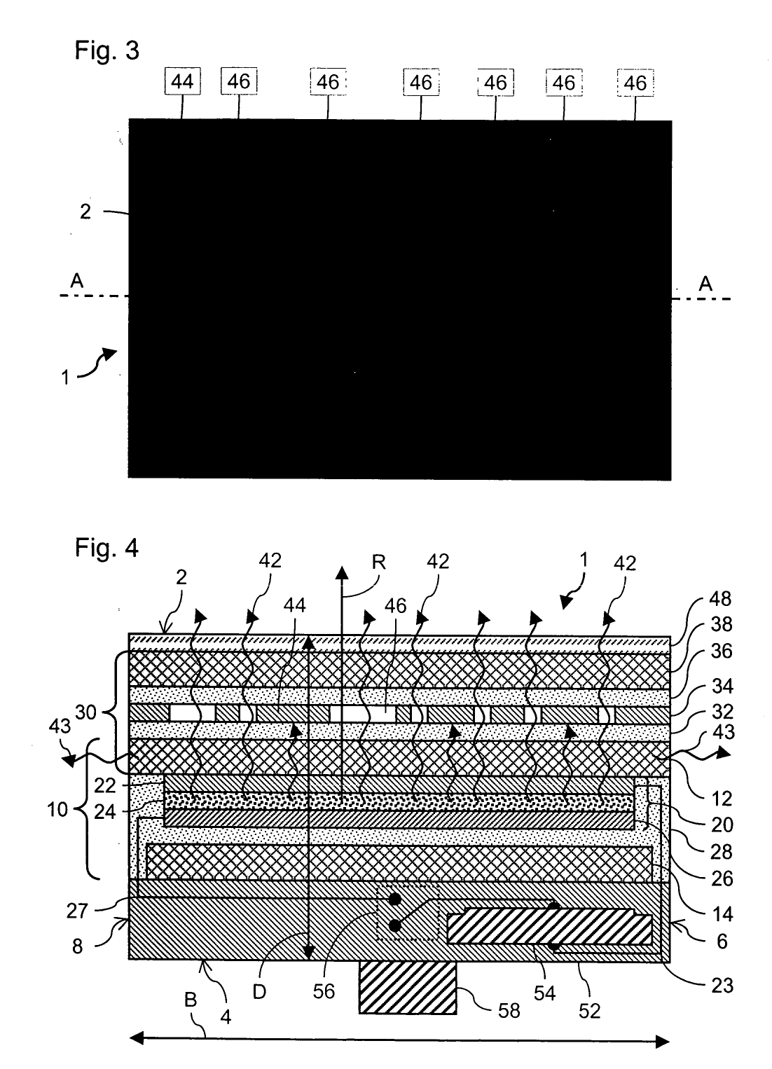

Referring to FIG. 3, a self-luminous name badge with the luminous lettering “SCHOTT”, defined by the light-transmissive sections 46, can be discerned. The self-luminous lettering is embedded in nonluminous, blackened surroundings, defined by the light-opaque sections 44 of the functional layer 34. The name badge 1 is laterally approximately 5 cm by 5 cm in size. It is possible even to produce signs or badges 1 having dimensions in both lateral directions of a few mm to 15 cm, to 50 cm or even larger.

In an advantageous manner, it is thus possible for virtually any desired luminous structure, in particular also with closed structures, such as the “O”, to be produced in a very simple manner.

The light-opaque or blackened sections furthermore have the advantage that the underlying sections of the light emitting layer arrangement are also concealed when the OLED is switched off.

What is furthermore advantageous is the independence in the production of the light emitting composite element 10, which is produced in unpatterned fashion as a standard mass-produced product, and the patterning or configuration, which can be performed independently by the purchaser by adhesively bonding or laminating on the layers 34 and, if appropriate, 38.

It is evident that this opens up a huge market potential in indication and/or sign technology. The organic light emitting device may e.g. also be used as a self-luminous door plate, house number, advertisement, information panel, road sign, etc.

Referring to FIG. 4, the name badge 1 shown in FIG. 3 comprises an antireflecting coating 48, which is applied on the protective substrate 38 to reduce reflection on its front side.

Furthermore, the name badge 1 comprises an integrated energy source or battery 54, which is optionally rechargeable and is fitted in a manner integrated in a dielectric housing 52 on the rear side 4 of the name badge 1.

The battery 54 is connected to the light emitting layer arrangement 20 via the leads 23, 27 and a switch 56.

The switch 56 is formed as a magnetically operated switch, is embedded in the housing 52 and is closed by the closing of a clip or holding clip, more precisely a magnetic clip 58. The holding clip 58 and the switch 56 thus interact with one another in such a way that the device or OLED 1 is automatically switched on if the user clamps or clips the OLED e.g. to his jacket and for this purpose closes the holding clip 58. As an alternative, the switch 56 may be integrated into the holding clip 58.

The overall structural height may in this case be, even including the housing 52 but, if appropriate, excluding the holding clip 58, between only 0.5 mm or 1 mm and 10 mm.

In this embodiment, the covering substrate 14 is smaller in its width B than the rest of the light emitting device. Furthermore, the leads are offset inwardly at the end sides 6 and 8 of the layers and cast in the adhesive layer 28, so that the end sides 6 and 8 and also the end sides that are perpendicular to the plane of the drawing are uncovered and accessible from the outside. After the encapsulation and/or completion of the device, the end sides are finally edge-processed, e.g. ground, in order to obtain a uniform and esthetically pleasing exterior.

Particular emphasis should also be given to the fact that, at the end sides of the base substrate 12, light 43 is coupled out transversely with respect to the main light coupling-out direction R, with the result that a luminous frame arises.

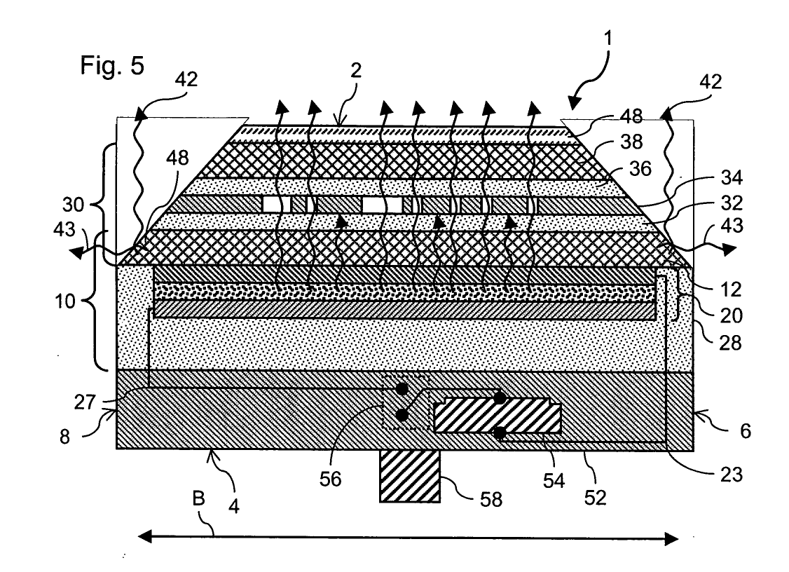

Referring to FIG. 5, the base substrate 12 and, if appropriate, further layers are beveled toward the front in the edge region 13, in order to obtain a coupling-out of light 43 in the direction R in the edge region.

In order to produce the device 1, firstly the light emitting composite element 10 is produced and sealed or encapsulated with the adhesive 28, the covering substrate 14 having been dispensed with in this example. The adhesive layer 32 is subsequently applied and the functional layer or film 34 is applied or adhesively bonded onto the light emitting composite element 10 on the exterior by means of the adhesive layer 32. The adhesive layer 36 is in turn subsequently applied to the film 34 and then the protective substrate 38 is adhesively bonded on. This method order is particularly advantageous if UV-curing adhesive is used, since an optimum coupling-in of light is achieved from above. If appropriate, the film 34 is patterned, e.g. photo patterned, only after it has been adhesively bonded on.

Particularly if a different adhesive is used, it is advantageous firstly for the protective substrate 38 and the film 34 to be adhesively bonded to form an intermediate composite element and for this intermediate composite element only afterward to be adhesively bonded onto the light emitting composite element 10 by means of the adhesive layer 32 since the light emitting composite element 10 is treated with care in this way.

It is evident to the person skilled in the art that the embodiments described above are to be understood by way of example, and the invention is not restricted thereto, but rather can be varied in diverse ways without departing from the spirit of the invention.

1. An organic light emitting device, comprising:
a first glass substrate;
an organic light emitting layer arrangement, wherein the organic light emitting layer arrangement comprises a first and second electrode and an organic electroluminescent layer;
an encapsulation encapsulating the organic light emitting layer arrangement, wherein the first glass substrate, the organic light emitting layer arrangement and the encapsulation form a light emitting composite element; and
a functional layer applied on the light emitting composite element, wherein the functional layer is an antishatter protective layer, and wherein at least the first glass substrate and the antishatter protective layer form a composite element.

2. (canceled)

3. The device as claimed in claim 1, wherein the encapsulation comprises a second substrate adhesively bonded on the first glass substrate or the organic light emitting arrangement.

4. The device as claimed in claim 3, further comprising a third substrate applied on the functional layer so that the functional layer is arranged between the first and third substrates, and wherein the first and third substrates and the antishatter protective layer form the composite element.

5. The device as claimed in claim 1, wherein the functional layer comprises first and second sections, wherein the first section is essentially light-transmissive and the second section is essentially light-opaque.

6. The device as claimed in claim 1, wherein the functional layer is a multicolor patterned mask.

7. The device as claimed in claim 1, wherein the functional layer comprises a plastic layer.

8. The device as claimed in claim 1, wherein the functional layer comprises a plastic film.

9. The device as claimed in claim 1, wherein the functional layer is adhesively bonded on the light emitting composite element.

10. The device as claimed in claim 1, wherein the functional layer comprises a self-adhesive film.

11. The device as claimed in claim 4, wherein the first and third substrates and the antishatter protective layer are adhesively bonded in areal fashion to form the composite element.

12. The device as claimed in claim 1, wherein the functional layer is adhesively bonded on the light emitting composite element by a crosslinking adhesive.

13. The device as claimed in claim 1, wherein the functional layer comprises a printed-on layer.

14. The device as claimed in claim 4, wherein the second and/or third substrate comprise a glass substrate.

15. The device as claimed in claim 4, wherein the first, second and/or third substrate comprise hardened glass.

16. The device as claimed in claim 4, wherein the first, second and/or third substrate comprise a glass-plastic composite.

17. The device as claimed in claim 4, wherein the first, second and/or third substrate comprise a plastic-coated glass or a laminated glass-plastic composite.

18. The device as claimed in claim 4, wherein the third substrate has an antireflection coating.

19. The device as claimed in claim 4, wherein the first, second and/or third substrate and/or the functional layer has opposing end sides.

20. The device as claimed in claim 1, wherein the organic light emitting device has at least one end side that is beveled.

21. The device as claimed in claim 4, wherein the first, second and/or third substrate has a thickness of 10 μm to 2000 μm.

22. The device as claimed in claim 4, wherein the first and second substrate are adhesively bonded to one another by a first adhesive layer, wherein the first substrate and the functional layer are adhesively bonded to one another by a second adhesive layer, and wherein the functional layer and the third substrate are adhesively bonded to one another by a third adhesive layer.

23. The device as claimed in claim 22, wherein the first, second and third adhesive layers each have a thickness of 3 μm to 100 μm.

24. The device as claimed in claim 1, wherein the organic light emitting device has a thickness of 150 μm to 10 mm.

25. The device as claimed in claim 1, further comprising an energy source and a switch for switching the organic light emitting device on and off.

26. The device as claimed in claim 3, wherein the second substrate defines a rear side of the organic light emitting device, and wherein a dielectric housing is fitted to the rear side, and wherein the dielectric housing has an energy source.

27. The device as claimed in claim 25, further comprising a holding clip that interacts with the switch in such a way that the switch is actuated by the holding clip.

28. (canceled)

29. The device as claimed in claim 27, wherein the switch is integrated in the holding clip.

30. The organic light emitting device as claimed in claim 1, wherein the organic light emitting device is adapted for use as a self-luminous information sign or a self-luminous information area.

31. A method for producing an organic light emitting device, comprising:
providing an organic light emitting composite element, wherein the organic light emitting composite element comprises a first glass substrate, an encapsulation and an organic light emitting layer arrangement;
encapsulating the organic light emitting layer arrangement by the first glass substrate and the encapsulation, wherein the organic light emitting layer arrangement comprises a first and second electrode and an organic electroluminescent layer;
applying a functional layer to the organic light emitting device, wherein the functional layer is an antishatter protective layer; and
producing a composite element comprising the first glass substrate and the antishatter protective layer.

32. The method as claimed in claim 31, wherein the applying step further comprises applying the functional layer to a front side of the organic light emitting device.

33. The method as claimed in claim 31, further comprising applying a third substrate to the functional layer.

34. The device as claimed in claim 19, wherein the opposing end sides are postprocessed after the second substrate is adhesively bonded to the first glass substrate or the organic light emitting arrangement.
